(19) United States
(12) Patent Application Publication
(10) Pub. No.: US 2010/0259322 A1
(43) Pub. Date: Oct. 14, 2010

(54) READOUT CIRCUIT AND SYSTEM INCLUDING SAME

(75) Inventors: Joseph R. Acquaviva, Gibsonia, PA (US); Arif Ahmed, Greensburg, PA (US)

Correspondence Address: REED SMITH LLP, P.O. BOX 488, PITTSBURGH, PA, 15230-0488, US

(73) Assignee: Bridge Semiconductor Corporation, Pittsburgh, PA (US)

(21) Appl. No.: 12/755,051

(22) Filed: Apr. 6, 2010

Related U.S. Application Data
(60) Provisional application No. 61/167,061, filed on Apr. 6, 2009.

(51) Int. Cl. H03K 17/687

(52) U.S. Cl. 327/603

(57) ABSTRACT

A readout circuit. The readout circuit includes a charge amplification circuit and an analog-to-digital conversion circuit. The analog-to-digital conversion circuit is connected to the charge amplification circuit.

### CROSS-REFERENCE TO RELATED APPLICATION

This application claims the benefit under 35 U.S.C. §119(e) of the earlier filing date of U.S. Provisional Patent Application No. 611167,061 filed on Apr. 6, 2009, the contents of which are hereby incorporated by reference in their entirety.

### BACKGROUND

This application discloses an invention which is related, generally and in various embodiments, to a readout circuit and a system including the readout circuit.

In various imaging systems, sensors are generally utilized to capture the original image. For some imaging systems, charge-coupled device (CCD) or complimentary metal oxide semiconductor (CMOS) sensors are utilized to convert light associated with a given image into electric charges. For other imaging systems, thermal sensors are utilized to convert temperatures (e.g., radiation in the 7 μm to 14 μm band) associated with a given image into electric charges. In many instances, for both light-based and thermal-based imaging systems, the electric charges produced by the sensors are then conditioned to produce related electronic signals. Such processing may include amplification, noise-correction, filtering, etc.

For thermal imaging systems, the electric charges produced by the sensors tend to be extremely small. In general, in order to make effective use of the electric charges, the electric charges are amplified to a suitable level. However, such amplification often produces undesirable consequences such as increased noise, weaker signal-to-noise ratios, etc.

### SUMMARY

In one general respect, this application discloses a readout circuit. According to various embodiments, the readout circuit includes a charge amplification circuit and an analog-to-digital conversion circuit. The analog-to-digital conversion circuit is connected to the charge amplification circuit.

In another general respect, this application discloses a system. According to various embodiments, the system includes a sensor and a readout circuit. The readout circuit is connected to the sensor, and includes a charge amplification circuit and an analog-to-digital conversion circuit. The charge amplification circuit is connected to the sensor. The analog-to-digital conversion circuit is connected to the charge amplification circuit.

Aspects of the invention may be implemented by a computing device and/or a computer program stored on a computer-readable medium. The computer-readable medium may comprise a disk, a device, and/or a propagated signal.

### BRIEF DESCRIPTION OF THE DRAWINGS

Various embodiments of the invention are described herein in by way of example in conjunction with the following figures, wherein like reference characters designate the same or similar elements.

FIG. 1 illustrates a high-level representation of a system according to various embodiments;

FIG. 2 illustrates a thermo-electric model of a sensor of the system of FIG. 1;

FIG. 3 is an illustrative example of temperature changes of the sensor of FIG. 1 due to a chopping process;

FIG. 4 illustrates a high-level representation of a readout circuit according to various embodiments of the system of FIG. 1;

FIG. 5 illustrates various embodiments of a charge amplification circuit of the readout circuit of FIG. 4;

FIG. 6 illustrates other embodiments of a charge amplification circuit of the readout circuit of FIG. 4;

FIG. 7 illustrates various embodiments of a digital-to-analog conversion circuit of the readout circuit of FIG. 4; and

FIG. 8 illustrates various embodiments of the system of FIG. 1.

### DETAILED DESCRIPTION

It is to be understood that at least some of the figures and descriptions of the invention have been simplified to illustrate elements that are relevant for a clear understanding of the invention, while eliminating, for purposes of clarity, other elements that those of ordinary skill in the art will appreciate may also comprise a portion of the invention. However, because such elements are well known in the art, and because they do not facilitate a better understanding of the invention, a description of such elements is not provided herein.

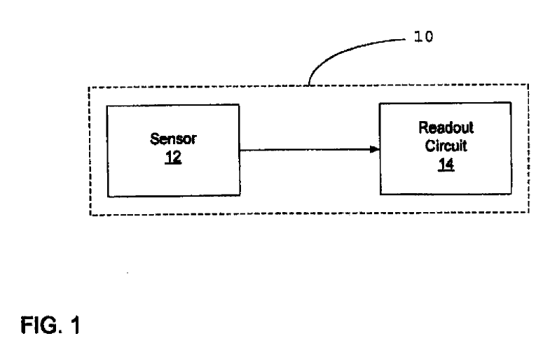

FIG. 1 illustrates a high-level representation a system 10. According to various embodiments, the system 10 includes a sensor 12, and a readout circuit 14 connected to the sensor 12. Although only one sensor 12 and one readout circuit 14 are shown in FIG. 1, it will be appreciated that the imaging system 10 may include a plurality of sensors 12 and a plurality of readout circuits 12. Each sensor 12 may be considered to be an individual pixel.

The sensor 12 may be embodied as any suitable type of sensor. According to various embodiments, the sensor 12 is a thermal sensor such as, for example, a thin-film Lead Zirconate Titanate (PZT) sensor. For purposes of simplicity, the system 10 will be described in the context of an imaging system having thermal sensors. However, it is understood that the system 10 may include any type and any number of sensors 12.

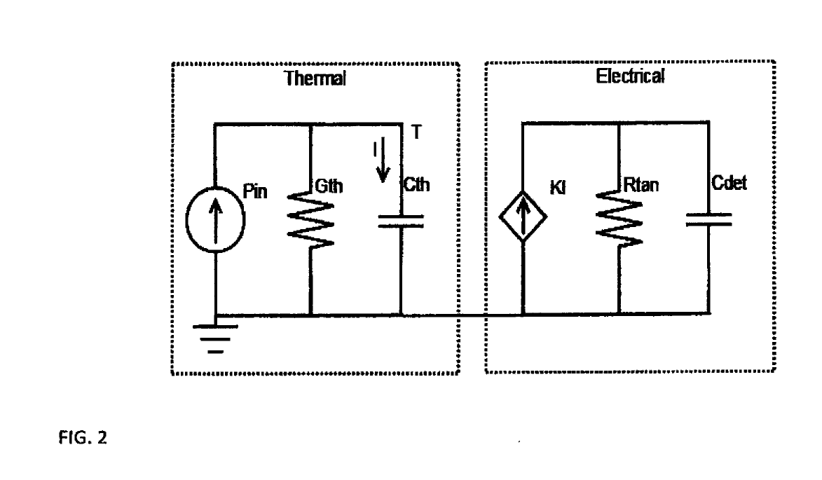

FIG. 2 illustrates a thermo-electric model of the thermal sensor 12 according to various embodiments. In general, a pyroelectric device such as the thermal sensor 12 utilizes a change in temperature in order to generate a useful signal. For example, objects in a scene of interest radiate energy to achieve thermal equilibrium with the environment, and it is this thermally generated radiation that is of interest to the thermal sensor 12. Simplistically, objects will radiate according to Planck's Blackbody Law:

$$I ( λ , T ) = \frac{2 {hc}^{2}}{{λ}^{5}} \frac{1}{{e}^{\frac{hc}{λ KT}} - 1} \qquad ( 1 )$$

where

I(λ, T)=spectral radiance per unit (time, wavelength, and solid angle)

h=Planck's constant

c=the speed of light

λ=wavelength

k=Boltzmann constant

In order to best detect an object in a given thermal scene, the object should stand out thermally from the background, therefore the difference in spectral radiance is a parameter of interest, and can be represented by the following equation:

ΔI=I(λ(Tₒ)−I(λ(T_{B}) (2)

where

Tₒ=temperature of the object

T_{B}=temperature of the background

It follows from equation (1) and equation (2) that:

$$Δ I ( λ , Δ T ) = {\int }_{{λ}_{1}}^{{λ}_{2}} \{ \frac{2 {hc}^{2}}{{λ}^{5}} \frac{1}{{e}^{\frac{hc}{λ {KT}_{0}}} - 1} \} d λ - {\int }_{{λ}_{1}}^{{λ}_{2}} \frac{2 {hc}^{2}}{{λ}^{5}} \frac{1}{{e}^{\frac{hc}{λ {KT}_{B}}} - 1} d λ \qquad ( 3 )$$

Equation (3) represents the incident power when integrated over wavelengths of interest. For a given thermal sensor 12, the value derived from equation (3) may be adjusted by the absorption efficiency of the pyroelectric material (Ti) of the thermal sensor 12, and may also be adjusted based on the lens and window transmission efficiency of the thermal sensor 12.

As the thermal sensor 12 operates under the pyroelectric effect, the thermal sensor 12 utilizes a change in temperature to produce a change in charge. Thermally, the thermal sensor 12 can be modeled as shown in FIG. 2. The power incident to the thermal sensor 12 is modeled as a current source Pᵢₙ, the thermal conductance of the thermal sensor 12 is modeled as Gₜₕ, and the thermal capacitance of the thermal sensor 12 is modeled as Cₜₕ. The temperature of the thermal sensor 12 can be derived from the following equation using frequency domain:

$$T = \frac{{P}_{in}}{{Y}_{eq}} = \frac{{P}_{in}}{{G}_{th} + {sC}_{th}} \qquad ( 4 )$$

where

Y_{eq}=the thermal admittance of the PZT sensor

s=the Laplace transform variable

As power (i.e., thermal radiation) is incident to the thermal sensor 12, the temperature of the thermal sensor 12 increases. If the power incident to the thermal sensor 12 is uninterrupted, the temperature of the thermal sensor 12 may reach a steady state value (e.g., a saturation temperature) after a period of time. Since the detector responds to a change in temperature, the system 10 may utilize a chopping system to modulate the power incident to the thermal sensor 12. In general, the chopping system periodically blocks the power incident to the thermal sensor 12, thereby periodically changing the temperature of the thermal sensor 12. The frequency of the blocking of the power incident to the thermal sensor 12 may be referred to as the chopping frequency.

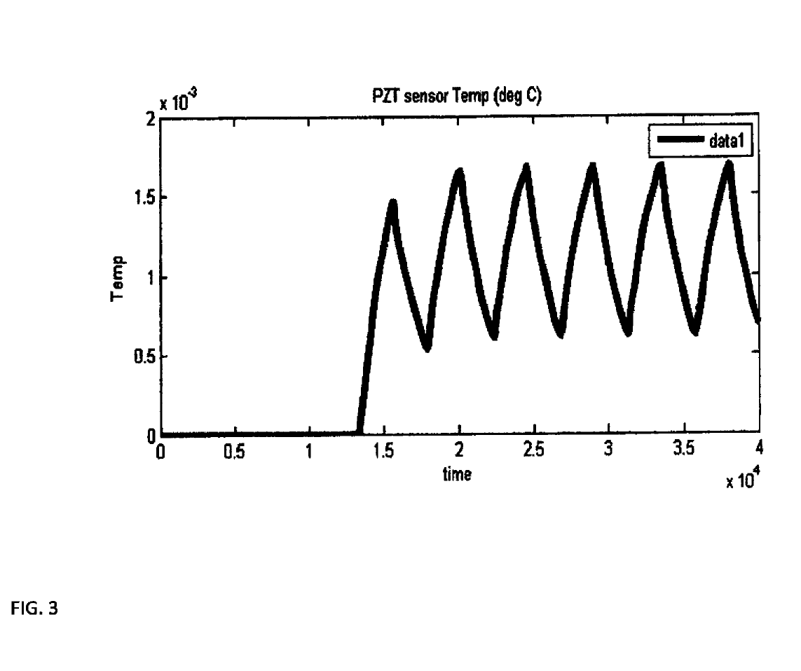

An illustrative example of the temperature changes of the thermal sensor 12 due to chopping is shown in FIG. 3. By modulating the incident power at the chopping frequency, the peak-to-peak value of the temperature of the thermal sensor 12 is reduced and does not reach steady state values. The magnitude of the peak-to-peak amplitude is related to the steady-state amplitude by the following equation:

$$Δ {T}_{chop} = Δ {T}_{max} tanh ( \frac{1}{4 {f}_{c} {τ}_{th}} ) \qquad ( 5 )$$

where

ΔT_{chop}=reduction in peak temperature

ΔTₘₐₓ=peak unchopped temperature

f_{c}=chopping frequency

τₜₕ=thermal time constant

For f_{c}=30 Hz and τₜₕ=16 ms, the chopping reduces the peak temperature of the thermal sensor 12 by a maximum of approximately 48%. As shown in FIG. 3, the peak to peak chop temperature is 1 mK, and this corresponds to a ΔQ of 0.4 femtocoulombs since charge is related to temperature difference by the following equation:

ΔQ=ηAₑₗΔT (6)

where

ΔQ=change in pyroelectric charge

η=pyroelectric coefficient (200 μC/m²K)

Aₑₗ=electrical area of the pixel (2×10⁻⁹ m²)

ΔT=change in pixel temperature

Electrically, the thermal sensor 12 can be modeled as shown in FIG. 2, where KI is a current source used to model the pyroelectric current, Rₜₐₙ, describes real losses in the dielectric material, and C_{det} is the intrinsic capacitance of the sensor 12.

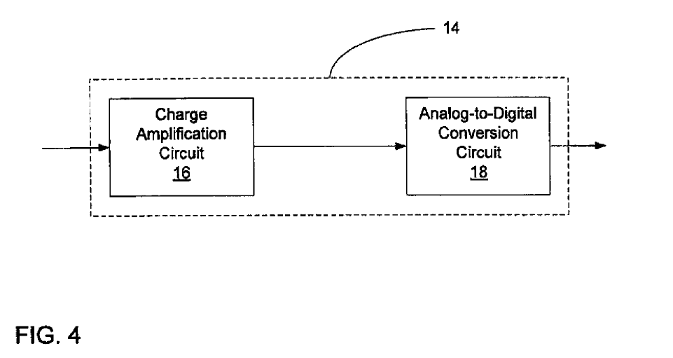

FIG. 4 illustrates a high-level representation of the readout circuit 14. According to various embodiments, the readout circuit 14 includes a charge amplification circuit 16 connected to the thermal sensor 12, and an analog-to-digital conversion circuit 18 connected to the charge amplification circuit 16.

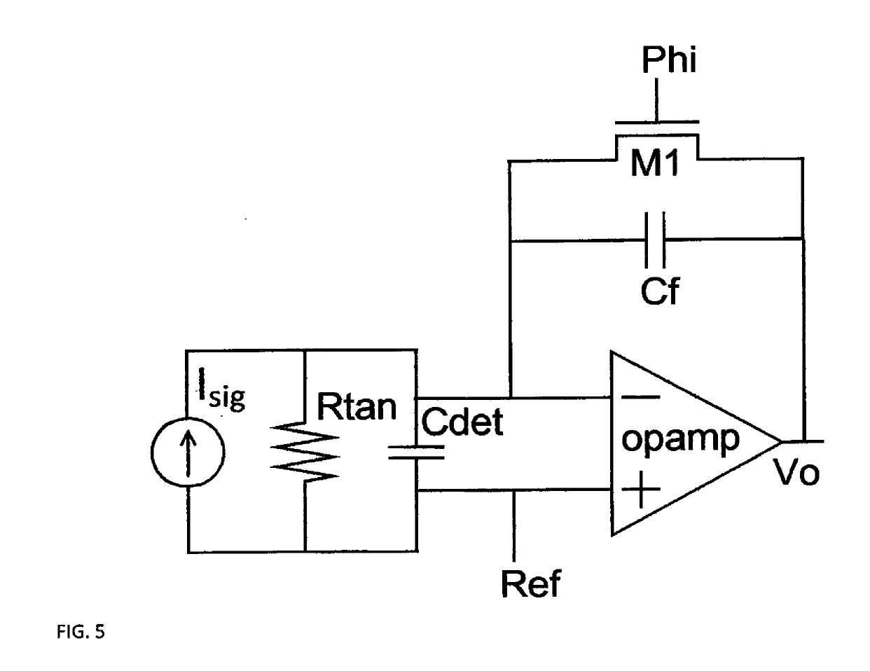

FIG. 5 illustrates various embodiments of the charge amplification circuit 16. The charge amplification circuit 16 includes an operational amplifier, a capacitor C_{f}, and a CMOS transmission gate M1. For purposes of simplicity, the CMOS transmission gate M1 is shown as a field-effect transistor. The operational amplifier has two input terminals (a non-inverting + and an inverting −) connected to the thermal sensor 12, and an output terminal connected to the analog-to-digital conversion circuit 18. The capacitor C_{f} and the CMOS transmission gate M1 are each connected between the inverting terminal of the operation amplifier and the output terminal of the operational amplifier. As shown in FIG. 5, the non-inverting terminal of the operational amplifier may be connected to a voltage source (Ref), and the charge amplification circuit 16 is configured as a capacitive trans-impedance amplifying circuit.

In operation, as the thermal sensor 12 heats and cools based on the incident radiation and the chopping, the thermal sensor 12 injects pyroelectric charge into the charge amplification circuit 16. This charge flows into the capacitor C_{f} and to the inverting input terminal of the operational amplifier. The operational amplifier differentially amplifies the charge to adjust the output voltage of the operation amplifier to sustain the charge at the capacitor C_{f}. Due to the differential amplification, the charge amplification circuit 16 of FIG. 5 operates to cancel common mode signals, and to cancel common mode noise. The differential architecture also minimizes the undesirable effects of clock feed through (e.g., charge leaking from the gate of the field-effect transistor to the drain and/or source of the field-effect transistor when the gate voltage is driven low) and charge injection (e.g., charge flowing from the channel of the field-effect transistor to the drain and/or source of the field-effect transistor after power to the gate of the field-effect transistor is interrupted).

If the voltage gain of the operational amplifier is made large enough, the capacitance at C_{f} will dominate C_{det} due to the Miller effect, and current will flow from the thermal sensor 12 to the capacitor C_{f}. The output voltage (Vₒ) of the operational amplifier is given by the following equation:

$${V}_{O} = \frac{{Q}_{det}}{{C}_{f}} ≅ \frac{2 ρ {A}_{el} Δ T}{{C}_{f}} provided ( 1 + {A}_{O} ) {C}_{f} >> {C}_{det} ;$$

where Aₒ is the open loop voltage gain

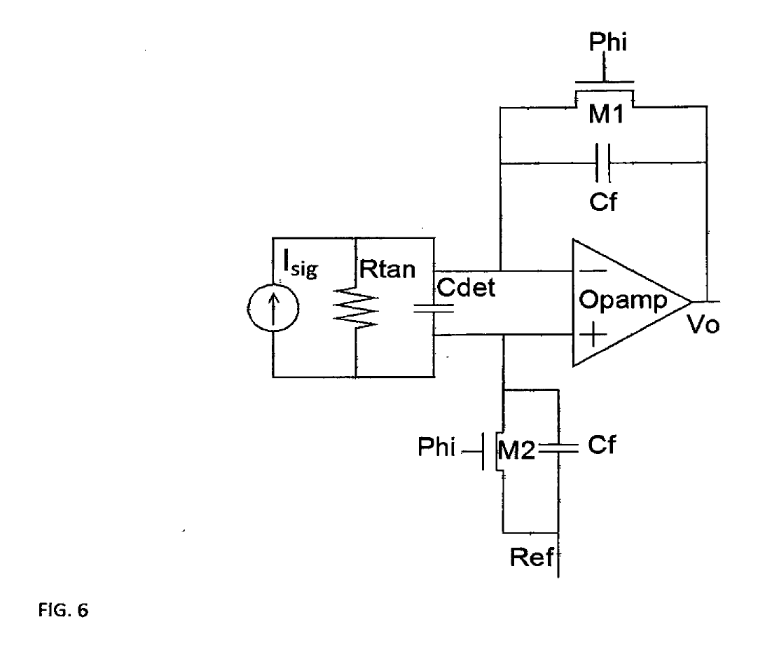

FIG. 6 illustrates other embodiments of the charge amplification circuit 16. As shown in FIG. 6, for such embodiments, the charge amplification circuit 16 includes an operational amplifier, a first capacitor C_{f}, a second capacitor C_{f}, a first CMOS transmission gate M1, and a second CMOS transmission gate M2. For purposes of simplicity, the first and second CMOS transmission gates M1, M2 are shown as field-effect transistors. The operational amplifier has two input terminals (a non-inverting + and an inverting −) connected to the thermal sensor 12, and an output terminal connected to the analog-to-digital conversion circuit 18. The first capacitor C_{f} and the first CMOS transmission gate M1 are each connected between the inverting terminal of the operation amplifier and the output terminal of the operational amplifier. The second capacitor C_{f} and the second CMOS transmission gate M2 are each connected to the non-inverting terminal of the operation amplifier. As shown in FIG. 6, the second capacitor C_{f} and the second CMOS transmission gate M2 may also be connected to a voltage source (Ref).

In some respects, the operation of the charge amplification circuit 16 of FIG. 6 is similar to the operation of the charge amplification circuit of FIG. 5. In general, a reset transition on the first and second CMOS transmission gates M1, M2 will couple charge (common mode) into the non-inverting and inverting terminals of the operational amplifier, thereby reducing its effect by the common mode rejection ratio of the operational amplifier. The charge amplification circuit 16 of FIG. 6 also operates to periodically cancel the offset associated with the operational amplifier, to periodically cancel drift associated with the operational amplifier, and to periodically cancel low frequency noise.

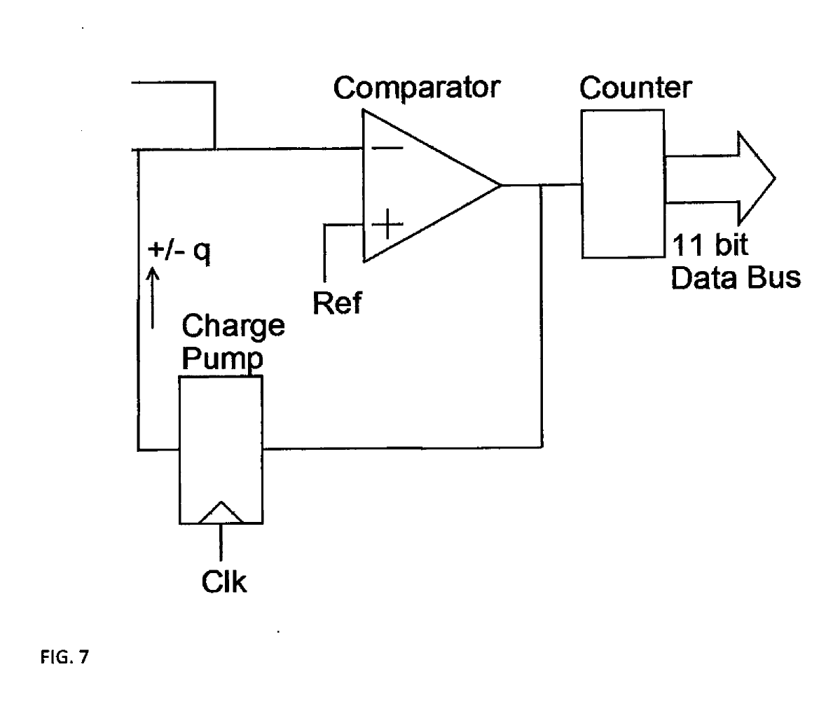

FIG. 7 illustrates various embodiments of the analog-to-digital conversion circuit 18 of the readout circuit 14. According to various embodiments, the analog-to-digital conversion circuit 18 is embodied as a sigma delta modulator circuit having a comparator and a charge pump. As shown in FIG. 7, the analog-to-digital conversion circuit 18 also includes a counter. According to various embodiments, the counter may be considered as part of the sigma delta modulator circuit.

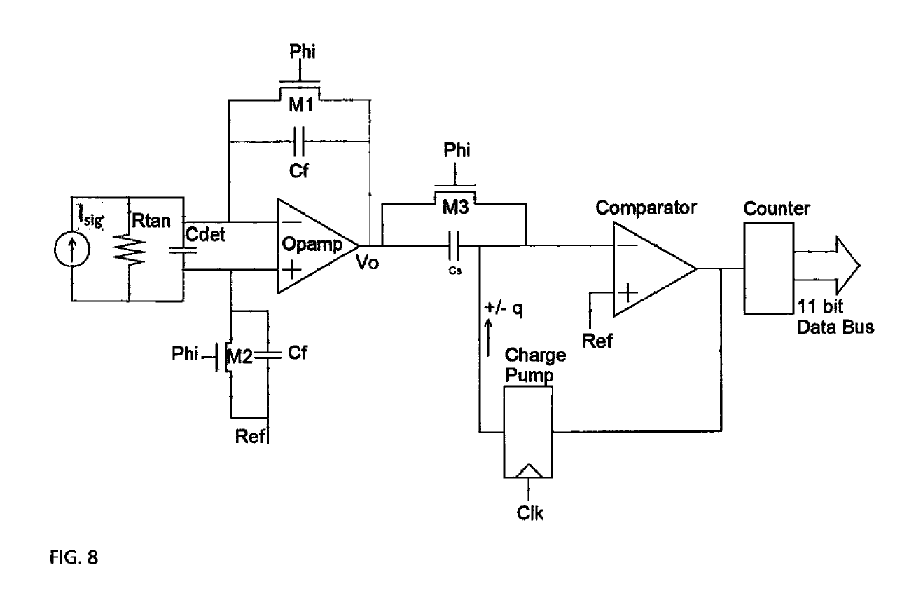

FIG. 8 illustrates various embodiments of the system 10. As shown in FIG. 8, the readout circuit 14 also includes a capacitor Cₛ and a third CMOS transmission gate M3. For purposes of simplicity, the third CMOS transmission gate M3 is shown as a field-effect transistor. According to various embodiments, the capacitor Cₛ and a third CMOS transmission gate M3 may be considered as part of the charge amplification circuit 16. According to other embodiments, the capacitor Cₛ and a third CMOS transmission gate M3 may be considered as part of the analog-to-digital conversion circuit 18 (e.g., as part of the sigma delta modulator circuit).

In operation, the readout circuit 14 of FIG. 8 operates as described hereinabove with respect to the charge amplification circuit 16 of FIG. 6. Based on the output voltage (Vₒ) of the operational amplifier, the charge on the capacitor Cₛ is equal to Vₒ*Cₛ, and is subsequently counted by the 1-bit sigma delta modulator circuit. The sigma delta modulator circuit will attempt to maintain the inverting terminal of the comparator at a voltage equal to V_{Ref} by delivering packets of charge ±q at the converter clock rate. The 11-bit counter tallies charge steps, and a digital representation of the input charge tally is recorded and delivered to the data bus. Each thermal sensor 12 is read during the light and dark phases of the chop cycle and a difference is taken digitally before resetting the clocking signal (Phi). This has the effect of imposing a correlated double sampling (CDS) process on the output data thereby reducing system offsets and reset noise.

Nothing in the above description is meant to limit the invention to any specific materials, geometry, or orientation of elements. Many part/orientation substitutions are contemplated within the scope of the invention and will be apparent to those skilled in the art. The embodiments described herein were presented by way of example only and should not be used to limit the scope of the invention.

Although the invention has been described in terms of particular embodiments in this application, one of ordinary skill in the art, in light of the teachings herein, can generate additional embodiments and modifications without departing from the spirit of, or exceeding the scope of, the described invention. Accordingly, it is understood that the drawings and the descriptions herein are proffered only to facilitate comprehension of the invention and should not be construed to limit the scope thereof.

What is claimed is:

1. A readout circuit, comprising:
a charge amplification circuit; and
an analog-to-digital conversion circuit connected to the charge amplification circuit.

2. The readout circuit of claim 1, wherein the charge amplification circuit comprises:
an operational amplifier, wherein the operational amplifier comprises:
a first input terminal;
a second input terminal; and
an output terminal;
a capacitor connected to the operational amplifier; and
a transmission gate connected to the capacitor.

3. The readout circuit of claim 2, wherein:
the first input terminal is a non-inverting input terminal; and
the second input terminal is an inverting input terminal.

4. The readout circuit of claim 3, wherein the first input terminal is connected to a voltage source.

5. The readout circuit of claim 3, wherein the second input terminal is connected to the capacitor.

6. The readout circuit of claim 2, wherein the second input terminal is connected to the transmission gate.

7. The readout circuit of claim 2, wherein the output terminal is connected to the capacitor.

8. The readout circuit of claim 2, wherein the output terminal is connected to the transmission gate.

9. The readout circuit of claim 2, wherein the capacitor comprises:
a first terminal connected to the second input terminal of the operational amplifier; and
a second terminal connected to the output terminal of the operational amplifier.

10. The readout circuit of claim 9, wherein the transmission gate comprises:
a first terminal connected to the first terminal of the capacitor; and
a second terminal connected to the second terminal of the capacitor.

11. The readout circuit of claim 2, wherein the transmission gate is a CMOS transmission gate.

12. The readout circuit of claim 2, wherein the transmission gate comprises:
a first terminal connected to the second input terminal of the operational amplifier; and
a second terminal connected to the output terminal of the operational amplifier.

13. The readout circuit of claim 2, wherein the charge amplification circuit further comprises:
a second capacitor, wherein the second capacitor is connected to the first terminal of the operational amplifier; and
a second transmission gate, wherein the second transmission gate is connected to the first terminal of the operational amplifier.

14. The readout circuit of claim 13, further comprising:
a third capacitor connected to the output terminal of the operational amplifier; and
a third transmission gate connected to the output terminal of the operational amplifier.

15. The readout circuit of claim 2, further comprising:
a second capacitor connected to the output terminal of the operational amplifier; and
a second transmission gate connected to the output terminal of the operational amplifier.

16. The readout circuit of claim 1, wherein the analog-to-digital conversion circuit comprises:
a sigma delta modulator circuit; and
a counter connected to the sigma delta modulator circuit.

17. The readout circuit of claim 16, wherein the sigma delta modulator circuit comprises:
a comparator, wherein the comparator comprises:
a first input terminal;
a second input terminal; and
an output terminal; and
a charge pump connected to the comparator.

18. The readout circuit of claim 17, wherein:
the first input terminal is a non-inverting input terminal; and
the second input terminal is an inverting input terminal.

19. The readout circuit of claim 17, wherein the charge pump is connected to:
the output terminal of the comparator; and
the second input terminal of the comparator.

20. The readout circuit of claim 17, wherein the sigma delta modulator circuit further comprises:
a capacitor connected to the first input terminal of the comparator; and
a transmission gate connected to the first input terminal of the comparator.

21. The readout circuit of claim 17, wherein the counter is connected to the output terminal of the comparator.

22. The readout circuit of claim 1, further comprising:
a capacitor connected to the charge amplification circuit and the sigma delta modulator circuit; and
a transmission gate connected to the charge amplification circuit and the sigma delta modulator circuit.

23. A system, comprising:
a sensor; and
a readout circuit connected to the sensor, wherein the readout circuit comprises:
a charge amplification circuit connected to the sensor; and
an analog-to-digital conversion circuit connected to the charge amplification circuit.

24. The system of claim 23, wherein the sensor is a thermal sensor.

25. The system of claim 23, wherein the system comprises:
a plurality of sensors; and
a plurality of readout circuits, wherein each readout circuit is connected to a different sensor.

26. The system of claim 23, wherein the system comprises a plurality of sensors connected to the readout circuit.
